(19) United States
(12) Patent Application Publication
(10) Pub. No.: US 2006/0148192 A1
(43) Pub. Date: Jul. 6, 2006

(54) Damascene MIM capacitor structure with self-aligned oxidation fabrication process

(75) Inventors: You-Hua Chou, Taipei (TW); Ling-Sung Wang, Hsin-Chu City (TW); Chih-Lung Lin, Taipei (TW); Tsung-Jen Shih, Pie-Guan Township (TW); Ying-Lang Wang, Tai-Chung County (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 11/029,727

(22) Filed: Jan. 4, 2005

(51) Int. Cl. H01L 21/20; H01L 21/8242

(52) U.S. Cl. 438/396; 438/393; 438/240

(57) ABSTRACT

A self aligned MIM capacitor structure and method for forming the same, the method including forming a metal filled damascene having an exposed surface in a dielectric insulating layer; forming a metal precursor layer on the exposed surface; carrying out a process on the metal precursor layer selected from the group consisting of oxidation and nitridation to form a capacitor dielectric portion; and, forming a conductive electrode on the capacitor dielectric portion.

### FIELD OF THE INVENTION

This invention generally relates to metal-insulator-metal (MIM) capacitor structures and more particularly to a damascene MIM stacked capacitor structure and method for forming the same including a self aligned ultra-thin dielectric material layer to achieve improved capacitor performance as well as an improved process flow.

### BACKGROUND OF THE INVENTION

Advances in technology have resulted in an increasing demand for system-on-chip products where both analog and digital signal processing are desirable. For example analog circuits capture an analog signal from the surrounding environment and transform the signal into bits which are then transformed into signals for driving digital circuitry and output functions. Increasingly it is advantageous to have both the analog circuitry and digital circuitry in close proximity, for example in the form digital blocks and analog blocks of circuitry which function together to implement the function of the system, also referred to as mixed mode systems.

For example, passive components (inductors, resistors, and capacitors) in analog/mixed-signal design passives are used for a wide variety of functions including tuning, filtering, impedance matching, and gain control. For example MIM capacitors are critical in several mixed signal integrated circuits such as analog frequency tuning circuits, switched capacitor circuits, filters, resonators, up-conversion and down-conversion mixers, and A/D converters.

In metal-insulator-metal (MIM) structures, which are included in analog circuitry building blocks, smaller capacitors are desirable from the standpoint of lower power consumption and increased feature density in a semiconductor device (chip).

Many analog and mixed mode systems rely on precise reproducibility in the electronic properties of circuit component structures, such as MIM structures, to achieve the electrical matching of the various circuitry components. Electronic mismatch of circuitry components results in reduced signal processing quality and is adversely affected by deviations in critical dimensions between components which is exacerbated by the increased number of processing steps generally required for producing the same component having different passive values, for example capacitance.

One approach to forming MIM electrodes structures in the prior art has included using high dielectric constant materials such as Ta₂O₅ as capacitor dielectric materials. One problem with high dielectric constant materials such as Ta₂O₅ are processing difficulties in removing excess material deposited by CVD or PVD methods to achieve a precisely formed dielectric capacitor thickness and capacitor area. As a result, capacitors may not be formed with the precision required as device sizes shrink, reducing device yield and device performance.

There is therefore a need in the semiconductor device processing art for improved MIM capacitor structures and manufacturing processes to achieve a higher degree of capacitor formation precision thereby increasing device yield and performance.

It is therefore an object of the invention to provide an improved MIM capacitor structure and manufacturing process to form the same to achieve a higher degree of capacitor formation precision thereby increasing device yield and performance, while overcoming other deficiencies and shortcomings of the prior art.

### SUMMARY OF THE INVENTION

To achieve the foregoing and other objects, and in accordance with the purposes of the present invention, as embodied and broadly described herein, the present invention provides a self aligned MIM capacitor structure and method for forming the same.

In a first embodiment, the method includes forming a metal filled damascene having an exposed surface in a dielectric insulating layer; forming a metal precursor layer on the exposed surface; carrying out a process on the metal precursor layer selected from the group consisting of oxidation and nitridation to form a capacitor dielectric portion; and, forming a conductive electrode on the capacitor dielectric portion.

These and other embodiments, aspects and features of the invention will become better understood from a detailed description of the preferred embodiments of the invention which are described in conjunction with the accompanying drawings.

### BRIEF DESCRIPTION OF THE DRAWINGS

FIGS. 1A-1G are cross-sectional views of a portion of an exemplary damascene MIM semiconductor structure at processing stages according to an embodiment of the present invention.

FIG. 2 is a process flow diagram including several embodiments of the present invention.

### DETAILED DESCRIPTION OF THE PREFERRED EMBODIMENTS

While the MIM capacitor structure and method for forming the same according to the present invention is described with reference to exemplary damascene structures it will be appreciated that the damascenes forming a lower electrode for the MIM capacitor structure may be formed of single or dual damascene structures and formed n parallel with other damascenes serving as metal interconnects for other circuitry portions of the semiconductor device.

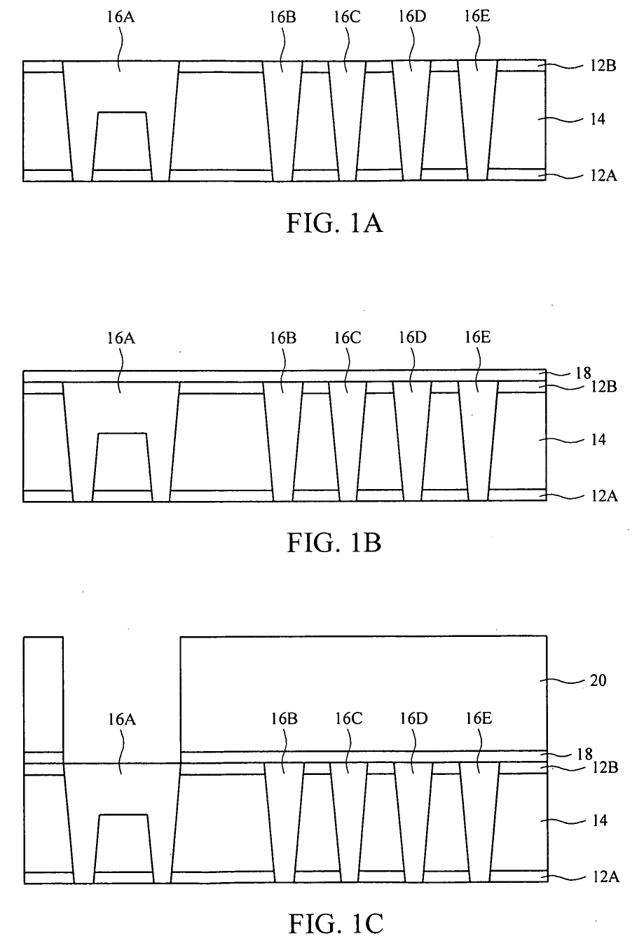

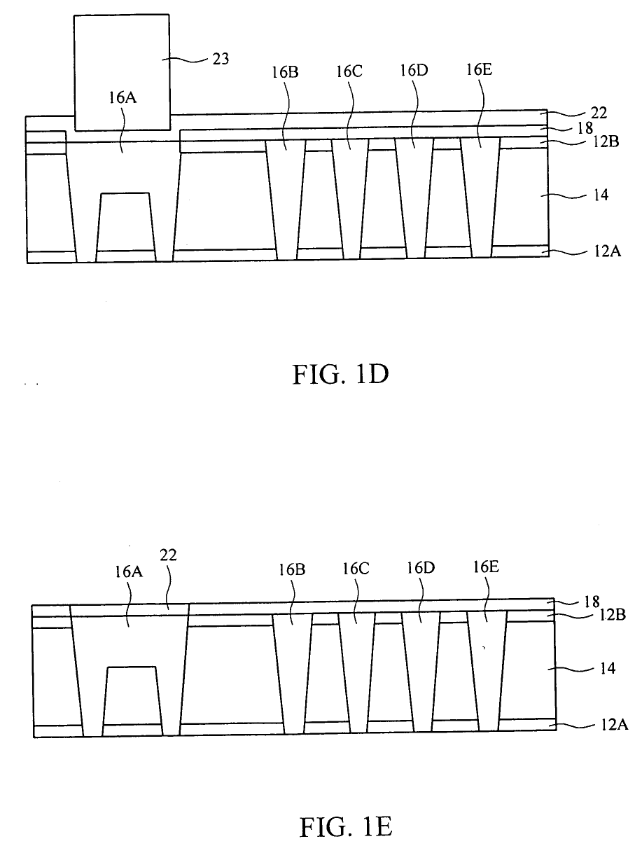

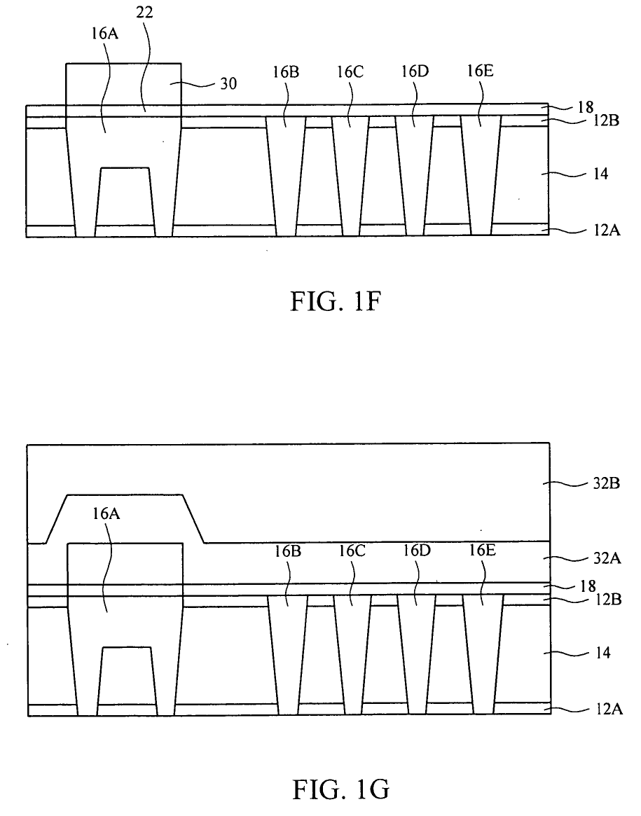

FIGS. 1A-1G show an exemplary embodiment of the present invention at stages in manufacture in forming an MIM structure. For example, referring to FIG. 1A is shown a first IMD layer 14, including copper filled dual damascenes e.g., 16A and single damascene structures e.g., 16B, 16C, 16D, and 16E, formed by conventional processes. For example a lower etch stop layer 12A is first formed by conventional CVD, PECVD, or HDPCVD processes over an underlying substrate (not shown), for example an underlying IMD or PMD layer including conductive interconnect structures which provide electrical communication with underlying semiconductor CMOS FET devices (not shown). For example, the lower etch stop layer 12A may be formed by conventional CVD, PECVD, or HDP-CVD processes of silicon carbide (e.g., SiC), either undoped or doped with nitrogen or oxygen (e.g., SiCN, SiCO), silicon nitride (e.g., SiN), or silicon oxynitride (e.g., SiON).

Still referring to FIG. 1A, the first IMD layer 14 is formed over the lower etch stop layer 12A by conventional CVD, PECVD, or HDPCVD processes of conventional dielectric insulating material including silicon oxide based doped or undoped materials. For example the IMD layer 14 may be formed of low-K silicon oxide based materials such as carbon doped silicon oxide or organo-silicate glass (OSG), but is preferably formed of undoped silicate glass (USG) or fluorinated silicate glass (FSG) for enhanced structural stability. An upper etch stop layer 12B, formed of the same preferred materials as outlined for the lower etch stop layer 12A, is then preferably formed over the IMD layer 14 by conventional processes, such as LPCVD, PECVD, and HDP-CVD to an appropriate thickness e.g., between about 300 Angstroms and 700 Angstroms.

Still referring to FIG. 1A, conventional patterning and etching processes are then carried out to form damascene openings followed by backfilling with a conductive material, e.g., a metal, by conventional PVD, CVD, or electrochemical (ECD) deposition processes to form dual damascenes e.g., 16A and/or single damascene structures e.g., 16B, 16C, 16D, and 16E. The backfilling metal may be one or more of Cu, AlCu, Ta, Ti, W, but is more preferably Cu. It will be appreciated the damascene openings may first be lined with a barrier layer such as a refractory metal and/or a refractory metal nitride.

In a preferred embodiment, the barrier layers are formed of TaN or Ti/TiN, preferably TaN, followed by backfilling with copper preferably according to an ECD process, followed by a CMP process to remove excess deposited copper overlying the surface to expose the upper etch stop layer 12B. It will be appreciated that other methods of deposition of copper such as PVD, CVD, or electroless deposition may be used to backfill the damascenes.

Referring to FIG. 1B, a capping layer 18 of silicon carbide (e.g., SiC), either undoped or doped with nitrogen or oxygen (e.g., SiCN, SiCO), silicon nitride (e.g., SiN), or silicon oxynitride (e.g., SiON), preferably SiC, is then formed (blanket deposited) over the process wafer surface to cover the exposed upper portions of the damascenes e.g., 16A, 16B, 16C, 16D, and 16E. The capping layer 18 may be formed having a thickness between about 100 Angstroms and 800 Angstroms.

Referring to FIG. 1C, a conventional photoresist patterning process is then carried out to form photoresist layer 20 to form an opening overlying one or more of the damascenes e.g., 16A, followed by a conventional dry etching process to remove a portion of the capping layer 18 to expose the underlying upper portion of the copper filled damascene, e.g., 16A.

Referring to FIG. 1D, in an important aspect of the invention a precursor layer 22 of a metal is blanket deposited by conventional PVD, CVD, atomic layer CVD (ALCVD) or other thin layer deposition process over the process wafer surface including the exposed copper damascene portions e.g., 16A and capping layer 18. In a preferred embodiment, the precursor metal layer 22 is deposited to a thickness of from about 10 to about 150 Angstroms, more preferably from about 10 to about 30 atomic layers e.g., about 15 to 50 Angstroms. Preferably the precursor metal layer 22 is capable of forming a capacitor dielectric material by subsequent oxidation or nitridation of the metal, the metal preferably having a lower oxidation reduction potential than copper. In a preferred embodiment, the precursor metal layer 22 is formed of Ta, W, Ti, or Al.

Still referring to FIG. 1D, a conventional photolithographic patterning process is then carried out to form a photoresist portion e.g., 23 covering the area overlying the damascene e.g., 16A. The uncovered precursor layer 22 portions are then removed by a conventional wet or dry etching process, preferably dry etching.

Referring to FIG. 1E, following removal of the photoresist portion 23, an oxidation or nitridation process is then carried out to oxidize an upper portion of the remaining precursor metal layer portion 22. The oxidation process may be by a plasma process including an oxygen atom and/or nitrogen atom plasma source gas to carry out respectively, metal layer 22 oxidation or nitridation. In addition, a thermal or chemical, more preferably a thermal oxidation or nitridation process to form a metal nitride or metal oxide surface layer on the metal precursor layer portion 22, e.g., preferably oxides or nitrides of Ta, W, Ti, or Al. For example, a furnace or rapid temperature anneal (RTA) thermal heating method, more preferably RTA, may be used with an appropriate nitrogen or oxygen atom source to respectively carry out the nitridation or oxidation process. For example, the oxygen atom gas source for the plasma or thermal oxidation may include one or more of CO, CO₂, N₂O, NO, O₃, O₂, more preferably consisting essentially of O₂. For example, the nitrogen atom gas source may include one or more of N₂, NH₂, CN, N₂O, NO etc, more preferably consisting essentially of N₂. It will be appreciated that other methods of heating the precursor metal over the damascene in an oxidizing or nitridation ambient may be used such as laser heating. Preferably, the heating or plasma process is carried out to oxidize an upper portion of the precursor metal layer 22, for example the upper 5 to 30 atomic layers, e.g., about 5 Angstroms to about 50 Angstroms, to form a self-aligned capacitor dielectric layer 22 by an oxidation or nitridation process. It will be appreciated that the thickness of the capacitor dielectric layer forming the upper portion of metal layer portion 22 may vary depending on the dielectric material formed, the desired capacitance, and the oxidation or nitridation treatment variables.

Referring to FIG. 1F, the MIM capacitor structure is completed by depositing an upper conductive electrode material layer, preferably a metal, more preferably an AlCu alloy, by a CVD or PVD deposition process. An anti-reflectance coating (ARC) layer (not shown) is first preferably formed followed by a conventional photolithographic patterning and dry etching process to form an upper electrode portion e.g., 30 overlying the self-aligned capacitor dielectric upper portion of precursor metal layer portion 22.

Referring to FIG. 1G, a dielectric insulating layer 32A, preferably FSG by a PECVD or HDP-CVD process, is then first blanket deposited to cover the process wafer surface, for example having a thickness at least about the thickness of the upper electrode 30 to add structural stability, followed by deposition of an overlying low-K silicon oxide based dielectric insulating layer 32B such as carbon doped oxide or organo-silicate glass (OSG), followed by a conventional oxide CMP process to planarize the surface. It will be appreciated that conventional damascene formation processes are then followed to form a metal filled interconnects (not shown), e.g., vias forming an electrical connection to the upper electrode 30, and/or the single damascene features e.g., 16B, 16C, 16D an 16E.

Thus, an improved MIM structure and method for forming MIM capacitor structures has been presented having an improved process flow and more precise control over the formation of ultra-thin capacitor layers, for example for use with characteristics device dimensions of 95 nm or less including 65 nm or less. Advantageously, conventional copper damascene formation processes are used to form the lower electrode portion of the MIM capacitor structure using previously formed single or dual damascenes, making the process flow more efficient compared to prior art processes. In addition, removal of excess portions of the precursor metal is more effectively accomplishes compared to removing excess capacitor dielectric material. In addition, by limiting formation of the dielectric capacitor material including oxides to upper portions of the metal precursor layer, damage such as oxidation of the copper damascene (lower electrode) is avoided thereby improving the reliability and yield of the MIM capacitor structure.

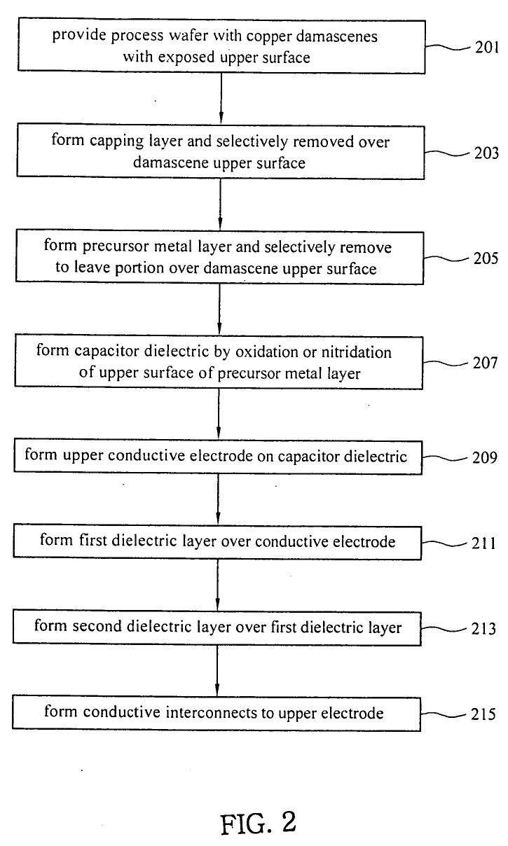

Referring to FIG. 2 is a process flow diagram including several embodiments of the present invention. In process 201, a semiconductor process wafer including exposed upper surface of copper filled damascenes is provided. In process 203, a capping layer is blanket deposited over the process wafer and selectively removed over the upper surface of copper filled damascenes. In process 205, a precursor metal is blanket deposited over the process wafer and selectively removed to leave a portion covering the upper surface of copper filled damascenes. In process 207, one of an oxidation and nitridation process of the precursor metal over the copper filled damascene is carried out to preferred embodiments to form a capacitor dielectric in upper portion of precursor metal layer. In process 209, an upper conductive electrode is formed on the capacitor dielectric. In process 211, a first dielectric insulating layer is formed over the upper electrode. In process 213, a second dielectric insulating layer is formed over the first dielectric insulating layer. In process 215, conductive interconnects are formed to the upper electrode to form an MIM capacitor structure.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method of forming a capacitor structure comprising the steps of:
forming a bottom electrode layer having an exposed surface;
forming a metal precursor layer by a metal precursor on the exposed surface of the bottom electrode layer;
carrying out a process on the metal precursor layer selected from the group consisting of an oxidation process and a nitridation process to form a capacitor dielectric portion; and
forming a top electrode layer on the capacitor dielectric portion.

2. The method of claim 1, further comprising the step of:
forming a dielectric insulating layer over the top electrode layer;
wherein, the dielectric insulating layer having a lower portion comprising fluorinated silicate glass (FSG) and an upper portion comprising a low-k silicon oxide based material.

3. The method of claim 2, wherein the low-k silicon oxide based material is selected from the group consisting of a carbon doped oxide and an organo-silicate glass (OSG).

4. The method of claim 1, wherein the bottom electrode layer is formed of a material selected from the group consisting of copper, aluminum and copper alloy.

5. The method of claim 1, wherein the metal precursor having a lower oxidation reduction potential with respect to the bottom electrode layer.

6. The method of claim 1, wherein the metal precursor is selected from the group consisting of Ta, W, Ti, and Al.

7. The method of claim 1, wherein the oxidation and nitridation process is selected from the group consisting of a plasma process, a heating process and a chemical treatment process.

8. The method of claim 7, wherein the plasma process and the heating process comprises a source of oxygen atoms for the oxidation process.

9. The method of claim 7, wherein the plasma process and the heating process comprises a source of nitrogen atoms for the nitridation process.

10. The method of claim 1, wherein the capacitor dielectric portion is formed to a thickness of from about ¼ to about ¾ of a thickness of an upper portion of the metal precursor layer.

11. The method of claim 1, wherein the upper electrode layer is selected form the group consisting of copper, aluminum, and alloys thereof.

12. The method of claim 1, wherein the bottom electrode layer is formed in a damascene structure in an inter-metal-dielectric (IMD) layer.

13. The method of claim 12, wherein the step of forming a metal precursor layer on the exposed surface comprises the steps of:
forming a capping layer overlying the exposed surface of the bottom electrode layer and the IMD layer;
removing the capping layer from the exposed surface of the bottom electrode layer;
blanket depositing the precursor metal layer overlying the capping layer and the exposed surface of the bottom electrode layer; and
removing portions of the precursor metal layer to leave the precursor metal layer overlying the exposed surface of the bottom electrode layer.

14. The method of claim 13, wherein the capping layer is formed of a material selected from the group consisting of silicon carbide, oxygen doped silicon carbide, nitrogen doped silicon carbide, silicon nitride, oxygen doped silicon nitride, and nitrogen doped silicon nitride.

15. A capacitor structure comprising:
a bottom electrode layer having an exposed surface;
a metal precursor layer of a metal precursor overlying the exposed surface of the bottom electrode layer;
a capacitor dielectric portion having from about ¼ to about ¾ of a thickness of an upper portion of the metal precursor layer, wherein the capacitor dielectric portion is formed of a material selected from the group consisting of oxides and nitrides of the metal precursor; and
a top electrode layer overlying the capacitor dielectric portion.

16. The capacitor structure of claim 15, further comprising:
a fluorinated silicate glass (FSG) layer overlying the top electrode layer; and
a low-k silicon oxide based material overlying the FSG layer.

17. The capacitor structure of claim 16, wherein the low-k silicon oxide based material is selected from the group consisting of carbon doped oxide and organo-silicate glass (OSG).

18. The capacitor structure of claim 15, wherein the bottom electrode layer is formed in a damascene structure in an inter-metal-dielectric (IMD) layer.

19. The capacitor structure of claim 15, wherein the bottom electrode layer is formed of a material selected from the group consisting of copper, aluminum and copper alloys.

20. The capacitor structure of claim 15, wherein the metal precursor layer is formed by a metal precursor having a lower oxidation reduction potential with respect to the bottom electrode layer.

21. The capacitor structure of claim 15, wherein the metal precursor is selected from the group consisting of Ta, W, Ti, and Al.

22. The capacitor structure of claim 15, wherein the capacitor dielectric portion having a thickness of from about 5 Angstroms to about 50 Angstroms.

23. The capacitor structure of claim 15, wherein the top electrode layer is formed of a material selected form the group consisting of copper, aluminum, and alloys thereof.
